(19) United States
(12) Patent Application Publication
(10) Pub. No.: US 2024/0112919 A1
(43) Pub. Date: Apr. 4, 2024

(54) Low-Temperature Etch

(71) Applicant: Tokyo Electron Limited, Tokyo (JP)

(72) Inventors: Du Zhang, Albany, NY (US); Maju Tomura, Miyagi (JP); Koki Mukaiyama, Miyagi (JP); Tomohiko Niizeki, Miyagi (JP); Yoshihide Kihara, Miyagi (JP); Mingmei Wang, Albany, NY (US)

(21) Appl. No.: 17/956,089

(22) Filed: Sep. 29, 2022

(51) Int. Cl. H01L 21/308

(52) U.S. Cl. CPC H01L 21/3081; H01L 21/3086

(57) ABSTRACT

A method of processing a substrate that includes: flowing dioxygen (O₂) and a hydrogen-containing gas into a plasma processing chamber that is configured to hold the substrate, the substrate including an organic layer and a patterned etch mask, the hydrogen-containing gas including dihydrogen (H₂), a hydrocarbon, or hydrogen peroxide (H₂O₂); generating an oxygen-rich plasma while flowing the gases; maintaining a temperature of the substrate in the plasma processing chamber between −150° C. and −50° C.; and while maintaining the temperature, exposing the substrate to the oxygen-rich plasma to form a recess in the organic layer.

### TECHNICAL FIELD

The present invention relates generally to methods of processing a substrate, and, in particular embodiments, to low-temperature etching of materials and systems.

### BACKGROUND

Generally, a semiconductor device, such as an integrated circuit (IC) is fabricated by sequentially depositing and patterning layers of dielectric, conductive, and semiconductor materials over a substrate to form a network of electronic components and interconnect elements (e.g., transistors, resistors, capacitors, metal lines, contacts, and vias) integrated in a monolithic structure. Many of the processing steps used to form the constituent structures of semiconductor devices are performed using plasma processes.

The semiconductor industry has repeatedly reduced the minimum feature sizes in semiconductor devices to a few nanometers to increase the packing density of components. Accordingly, the semiconductor industry increasingly demands plasma processing technology to provide processes for patterning features with accuracy, precision, and profile control, often at atomic scale dimensions. Meeting this challenge along with the uniformity and repeatability needed for high volume IC manufacturing requires further innovations of plasma processing technology.

### SUMMARY

In accordance with an embodiment of the present invention, a method of processing a substrate that includes: flowing dioxygen (02) and a hydrogen-containing gas into a plasma processing chamber that is configured to hold the substrate, the substrate including an organic layer and a patterned etch mask, the hydrogen-containing gas including dihydrogen (H₂), a hydrocarbon, or hydrogen peroxide (H₂O₂); generating an oxygen-rich plasma while flowing the gases; maintaining a temperature of the substrate in the plasma processing chamber between −150° C. and −50° C.; and while maintaining the temperature, exposing the substrate to the oxygen-rich plasma to form a recess in the organic layer.

In accordance with an embodiment of the present invention, a method of processing a substrate that includes: cooling the substrate in a plasma processing chamber to a temperature of −50° C. or lower, the substrate including a dielectric layer, an amorphous carbon layer (ACL) and a patterned etch mask; flowing dioxygen (O₂) and a hydrogen-containing gas into a plasma processing chamber; generating a plasma in the plasma processing chamber, where portions of dioxygen and the hydrogen-containing gas react under the plasma to form water (H₂O) molecules; and exposing the substrate to the plasma to form a recess in the organic layer, the recess having an aspect ratio of at least 20:1, the substrate being kept at around the temperature.

In accordance with an embodiment of the present invention, a method of forming a high-aspect ratio (HAR) feature on a substrate in a plasma processing chamber that includes: depositing an amorphous carbon layer (ACL) hardmask over a dielectric layer including silicon oxide formed over the substrate; depositing and pattern an etch mask layer over the ACL hardmask; flowing dioxygen(O₂), a hydrogen-containing gas, and a noble gas to a plasma processing chamber; generating a halogen-free and sulfur-free plasma in the plasma processing chamber while flowing O₂, the hydrogen-containing gas, and the noble gas, where portions of O₂ and the hydrogen-containing gas react under the plasma to form water (H₂O) vapor; maintaining a temperature of the substrate between −150° C. and −50° C.; patterning the ACL hardmask by exposing the substrate to the halogen-free and sulfur-free plasma in the plasma processing chamber, while maintaining the temperature of the substrate, to the plasma; and forming a HAR feature in the a dielectric layer by etching the dielectric layer using the patterned ACL hardmask as an etch mask, the HAR feature having an aspect ratio of at least 20:1.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1A-1C illustrate cross sectional views of a substrate during an example process of semiconductor fabrication comprising a plasma etch process to form a high aspect ratio (HAR) feature on the substrate in accordance with various embodiments, wherein FIG. 1A illustrates an incoming substrate comprising an underlying layer, a material layer, and a patterned mask layer, FIG. 1B illustrates the substrate during the formation of the HAR feature in the material layer by the plasma etch process, and FIG. 1C illustrates the substrate after a subsequent plasma etch process to etch the underlying layer;

FIGS. 2A-2B illustrate cross sectional views of a substrate during the plasma etch process, wherein FIG. 2A illustrates the substrate where etchant species causes lateral etching, and FIG. 2B illustrates the substrate where a passivation layer prevents lateral etching;

FIG. 3 illustrates a schematic surface structure of amorphous carbon layer (ACL) with H₂O adsorption;

FIG. 4 illustrates a simulated surface coverage by H₂O as a function of temperature at different partial pressures;

FIGS. 5A-5C illustrate process flow diagrams of methods of semiconductor fabrication comprising a plasma etch process to form a HAR feature in accordance with various embodiments, wherein FIG. 5A illustrates an embodiment, FIG. 5B illustrates an alternate embodiment, and FIG. 5C illustrates yet another embodiment; and

FIG. 6 illustrates a plasma system for performing a process of semiconductor fabrication in accordance with various embodiments.

### DETAILED DESCRIPTION OF ILLUSTRATIVE EMBODIMENTS

This application relates to fabrication of semiconductor devices, for example, integrated circuits comprising semiconductor devices, and more particularly to high capacity three-dimensional (3D) memory devices, such as a 3D-NAND (or vertical-NAND), 3D-NOR, or dynamic random access memory (DRAM) device. The fabrication of such devices may generally require forming conformal, high aspect ratio (HAR) features (e.g., a contact hole) of a circuit element. Features with aspect ratio (ratio of height of the feature to the width of the feature) higher than 50:1 are generally considered to be high aspect ratio features, and in some cases fabricating a higher aspect ratio such as 100:1 may be desired for advanced 3D semiconductor devices. In such applications, HAR features may be formed in a dielectric layer (e.g., silicon oxide, silicon nitride, or oxide/nitride layer stack) by a highly anisotropic plasma etch process with high fidelity. To enable ideal etch performance for HAR features, an etch mask, for example, amorphous carbon layer (ACL), must with a HAR also be prepared prior to etching the dielectric layer. This etch process for the etch mask (e.g., ACL) may be based on O₂-sulfur chemistry to achieve highly vertical etch profile, high etch rate with minimal irregularities (e.g., contact edge roughness, line edge roughness, and/or line width roughness). However, the use of sulfur in the etch process, although helpful in passivating sidewalls to minimize lateral etching, can cause acidic contamination during the process. Therefore, a new etch method that does not require sulfur may be desired for patterning an etch mask with high aspect ratio (HAR). Embodiments of the present application disclose methods of fabricating HAR features by a plasma etch process based on a combination of H₂O-based sidewall passivation and low-temperature plasma etching conditions.

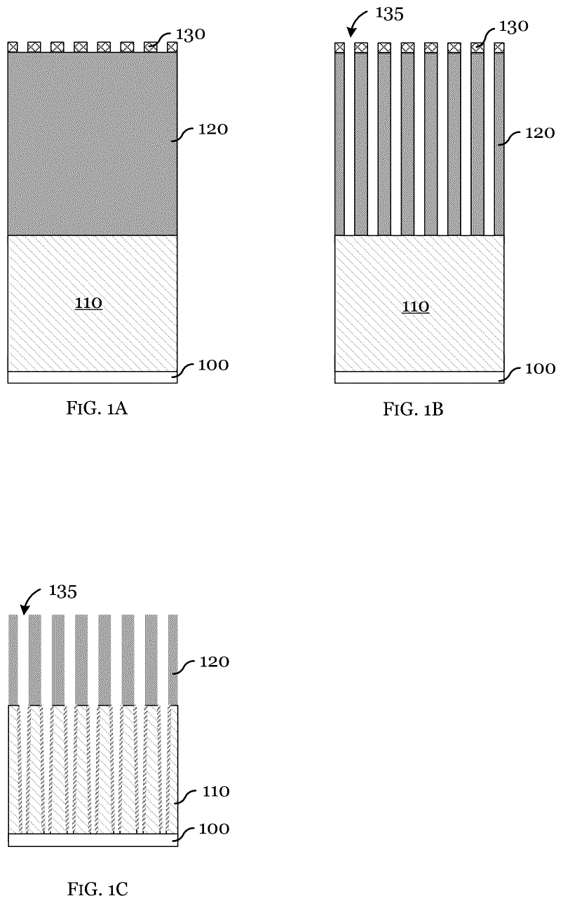

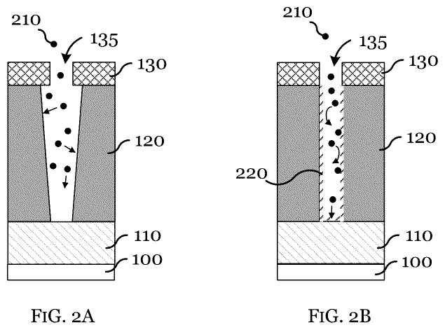

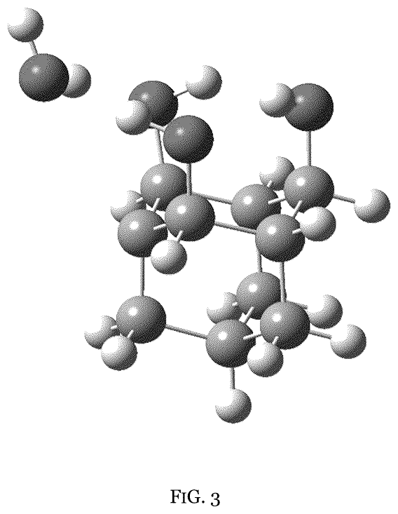

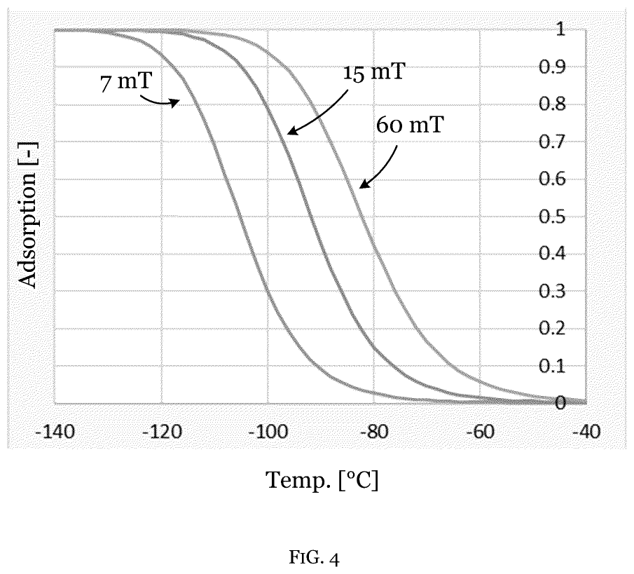

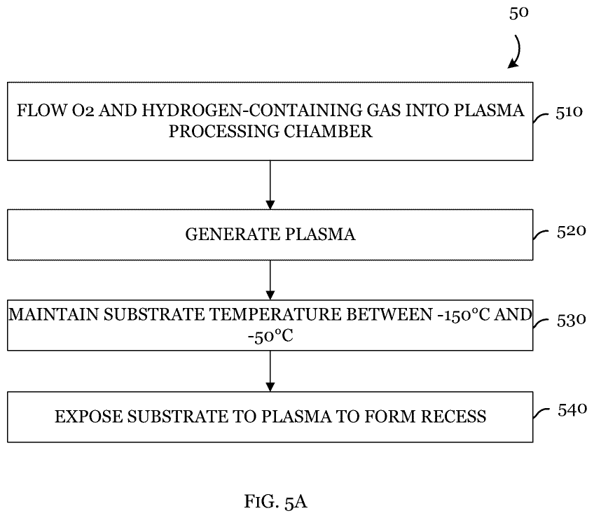

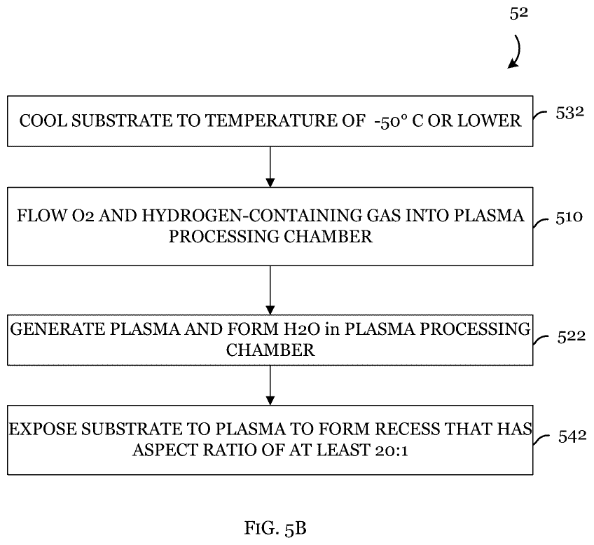

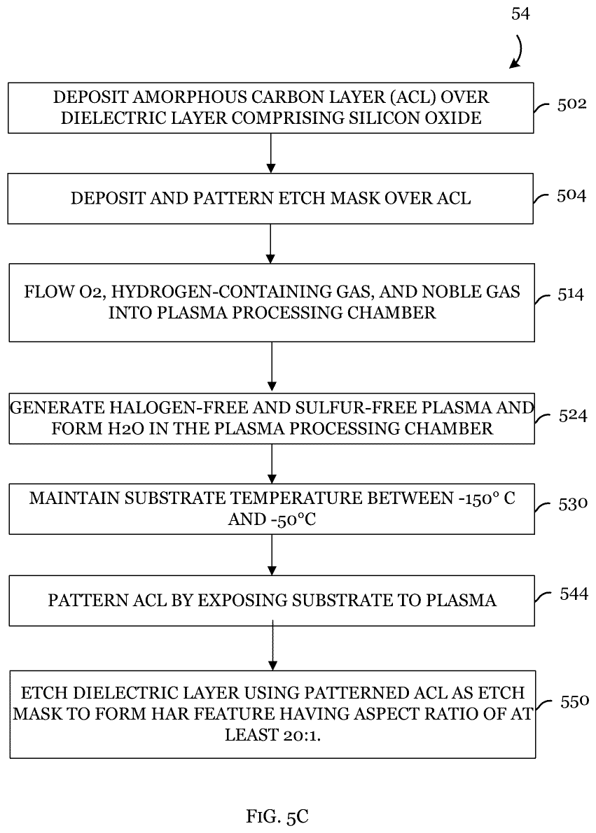

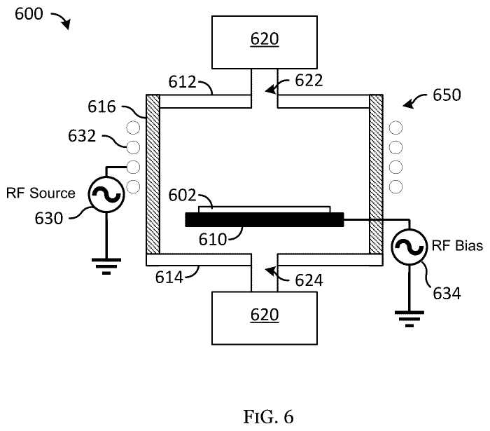

In the following, an exemplary plasma etch process to form a high aspect ratio (HAR) feature is described in accordance with various embodiments referring to FIGS. 1A-1C. The effect of sidewall passivation by a passivation layer is then described referring to FIGS. 2A-2B. Subsequently, the H₂O adsorption at low-temperature conditions is described referring to FIGS. 3 and 4. Example process flow diagrams are then illustrated in FIG. 5A-5C. FIG. 6 provides an example inductively coupled plasma (ICP) system for performing a process of semiconductor fabrication in accordance with various embodiments. All figures are drawn for illustration purpose only and not to scale, including the aspect ratios of features.

FIGS. 1A-1D illustrate cross sectional views of a substrate during an example process of semiconductor fabrication comprising a plasma etch process to form a high aspect ratio (HAR) feature on the substrate in accordance with various embodiments.

FIG. 1A illustrates an incoming substrate 100 comprising an underlying layer 110, a material layer 120, and a patterned mask layer 130.

In one or more embodiments, the substrate 100 may be a silicon wafer, or a silicon-on-insulator (SOI) wafer. In certain embodiments, the substrate 100 may comprise a silicon germanium wafer, silicon carbide wafer, gallium arsenide wafer, gallium nitride wafer and other compound semiconductors. In other embodiments, the substrate comprises heterogeneous layers such as silicon germanium on silicon, gallium nitride on silicon, silicon carbon on silicon, as well layers of silicon on a silicon or SOI substrate.

In various embodiments, the substrate 100 is a part of, or include, a semiconductor device, and may have undergone a number of steps of processing following, for example, a conventional process. For example, the semiconductor structure may comprise a substrate 100 in which various device regions are formed. At this stage, the substrate 100 may include isolation regions such as shallow trench isolation (STI) regions as well as other regions formed therein. Accordingly, the substrate 100 is used to collectively refer to any structures formed therein.

The underlying layer 110 may be formed over the substrate 100. In various embodiments, the underlying layer 110 is a target layer that is to be patterned by a subsequent plasma etch process after patterning the material layer 120. In certain embodiments, the feature being etched into the underlying layer 110 may be a contact hole, slit, or other suitable structures comprising a recess. In various embodiments, the underlying layer 110 may comprise a dielectric material. In certain embodiments, the underlying layer 110 may be a silicon oxide layer. In alternate embodiments, the underlying layer 110 may comprise silicon nitride, silicon oxynitride, or an O/N/O/N layer stack (stacked layers of oxide and nitride). The underlying layer 110 may be deposited using an appropriate technique such as vapor deposition including chemical vapor deposition (CVD), physical vapor deposition (PVD), atomic layer deposition (ALD), as well as other plasma processes such as plasma enhanced CVD (PECVD) and other processes. In one embodiment, the underlying layer 110 has a thickness between 1 μm and 10 μm.

Still referring to FIG. 1A, the material layer 120 is formed over the underlying layer 110. In various embodiments, the material layer 120 may comprise amorphous carbon layer (ACL). In certain embodiments, the material layer 120 may comprise a layer stack of multiple mask materials (e.g., soft ACL and hard ACL). The material layer 120 may be deposited using, for example, an appropriate spin-coating technique or a vapor deposition technique such as chemical vapor deposition (CVD), physical vapor deposition (PVD), atomic layer deposition (ALD), as well as other plasma processes such as plasma enhanced CVD (PECVD) and other processes. The relative thicknesses of the material layer 120 and the underlying layer 110 may have any suitable relationship. For example, the material layer 120 may be thicker than the underlying layer 110, thinner than the underlying layer 110, or the same thickness as the underlying layer 110. In certain embodiments, the material layer 120 has a thickness between 1 μm and 4 μm. In one embodiment, the material layer 120 comprises amorphous carbon layer (ACL) and has a thickness of 2.5 μm. In various embodiments, the material layer 120 is the layer to be patterned to form HAR features by the plasma etch process.

Further illustrated in FIG. 1A, the substrate 100 may comprise the patterned mask layer 130 over the material layer 120. In various embodiments, the patterned mask layer 130 may comprise a silicon mask material, such as silicon oxynitride (SiON). The patterned mask layer 130 may be formed by first depositing a mask layer using, for example, an appropriate vapor deposition technique such as chemical vapor deposition (CVD), physical vapor deposition (PVD), atomic layer deposition (ALD), as well as other plasma processes such as plasma enhanced CVD (PECVD) and other processes. The deposited mask layer may then be patterned using a lithography process and an anisotropic etch process.

Although not specifically illustrated in FIG. 1A, the substrate 100 may also comprise other layers. For example, for the purpose of patterning the mask layer, a tri-layer structure comprising a photoresist layer, SiARC layer, and optical planarization layer (OPL) may be present.

Fabricating the HAR feature in the material layer 120 may be performed by a plasma etch process based on O₂ etch chemistry. In various embodiments, an oxygen-containing gas such as dioxygen (O₂) may be used as a primary etch gas. In addition, a hydrogen-containing gas may be included in a process gas such that, under a plasma condition, water (H₂O) vapor may be formed in a plasma processing chamber. The inventors of this application identified that the water molecules formed may be adsorbed on surface at a sufficiently low temperature and advantageously provide sidewall passivation during the plasma etch process to form the HAR feature. In various embodiments, to enable the sidewall passivation with H₂O, low-temperature conditions (e.g., <−50° C.) may be used. In various embodiments, the hydrogen-containing gas may comprise dihydrogen (H₂), a hydrocarbon (e.g., CH₄), or hydrogen peroxide (H₂O₂). In certain embodiments, other gases such as a noble gas and/or a balancing agent may also be added.

The addition of the hydrogen-containing gas in the process gas may also benefit the etch rate, which may in turn enable a shorter process time compared to conventional HAR etch methods. Although not wishing to be limited by any theory, the addition of the hydrogen-containing gas may advantageously enhance the dissociation of O₂ in the plasma and increase the number of reactive species such as oxygen radicals. In addition, the formation of the physisorbed H₂O at the etch front may also serve as an etchant layer to assist in reactive ion etching, specifically by releasing atomic O and H upon ion bombardment, leading to etch by-product formation.

Conventional methods of etching carbon materials such as amorphous carbon layer (ACL) may use O₂ and sulfur, where sulfur is added for sidewall passivation. Sulfur, however, may cause acidic contamination. With a cleaner alternative of H₂O-based passivation, the methods described in this disclosure may advantageously eliminate the need of sulfur while maintaining or improving the etch rate. Accordingly, in various embodiments, the plasma used in the plasma etch process may be a sulfur-free plasma. Similarly, the plasma may be a halogen-free plasma in certain embodiments. Avoiding halogen for the methods of etching carbon materials such as ACL may be particularly advantageous for fabricating HAR structures, for example, for 3D-NAND devices. This is because such a fabrication process typically involves (1) ACL patterning, followed by (2) a dielectric etch using the patterned ACL as an etch mask, and halogen-free etch chemistry in the ACL patterning can provide better etch selectivity to the etch mask for ACL patterning (e.g., the patterned mask layer 130 in FIG. 1A, for example, SiON) and an underlying dielectric layer (e.g., the underlying layer 110 in FIG. 1A, for example, SiO₂, Si₃N₄, or O/N/ON stack structures). The ACL patterning may typically be performed using an inductively-coupled plasma (ICP) system. On the other hand, the subsequent dielectric etch may use a halogen-based etch chemistry, for example, using fluorine species as a main etchant, in order to effectively etch Si-containing materials (e.g., SiON and SiO₂). The subsequent dielectric etch may typically be performed using a capacitively-coupled plasma (CCP) system.

FIG. 1B illustrates the substrate 100 during the formation of the HAR feature in the material layer 120 by the plasma etch process.

In FIG. 1B, the high aspect ratio (HAR) feature is formed as recesses 135 in the material layer 120 by the plasma etch process. In various embodiments, the HAR feature has an aspect ratio (depth to width) of more than 20. In one or more embodiments, the aspect ratio may be between 50 and 500, and more than 100 in one example. As illustrated in FIG. 1B, the recesses 135 may be formed straight and uniformly across the substrate 100 with a minimal level of bowing. Bowing refers to the deviation of a perfectly straight recess from a purely anisotropic profile to a recess having outward curvature. Bowing may generally occur near the top of sidewalls of the etch target (e.g., the material layer 120), and may be caused by the bending of incident ion trajectories of ions used during the plasma etching process. Bowing may be eliminated or minimized by the sidewall passivation in the recess 135, as further illustrated below referring to FIGS. 2A and 2B.

In various embodiments, process parameters may be selected to optimize the characteristics of the high aspect ratio (HAR) feature considering various factors comprising etch rate, selectivity to the etch mask (e.g., the patterned mask layer 130), sidewall passivation in the HAR feature, and good critical dimension uniformity (CDU) among others. The process parameters may comprise gas selection, gas flow rates, pressure, temperature, process time, and plasma conditions such as source power, bias power, RF pulsing conditions.

In certain embodiments, a ratio of a flow rate of the oxygen-containing gas (e.g., O₂) to a flow rate of the hydrogen-containing gas (e.g., H₂) may be between 100:1 and 1:1. In one or more embodiments, the ratio of the flow rate may be between 20:1 and 10:1. In various embodiments, the gas composition and their flow rates may be selected to obtain an oxygen-rich plasma for the plasma etch process, which can be generally used for etching carbon materials such as ACL. In the oxygen-rich plasma, reactive species are predominantly oxygen-containing species, where the amount of oxygen-absent species are not greater than that of oxygen-containing species. In certain embodiments, the plasma may be an oxygen-rich, halogen-free plasma.

In various embodiments, the substrate temperature may be kept at a low temperature such that sufficient H₂O adsorption may be enabled. Accordingly, a low temperature in this disclosure may refer to a temperature of −50° C. or lower. In certain embodiments, the substrate temperature may be kept between −150° C. and −50° C., or between −120° C. and −70° C. in another embodiment, during the plasma etch process. A total pressure in the plasma processing chamber may be kept between 0.1 mTorr and 500 mTorr. In one embodiment, the process conditions may comprise the following: an etch time of 60 seconds, a pressure of 15 mTorr, a source power of 2500 W, a bias power of 570 W, an O₂ flow rate of 360 sccm, a H₂ flow rate of 40 sccm, and a substrate temperature of −50° C.

The recesses 135 may be in any shapes and structures, including a contact hole, slit, or other suitable structures comprising a recess useful for semiconductor device fabrication. In various embodiments, the features defined by the recesses 135 has a critical dimension (CD) of 200 nm or less. In certain embodiments, the CD may be between 50 nm and 200 nm. For example, the feature may comprise a slit with a CD of about 150 nm. In alternate embodiments, the recesses 135 may comprise a hole that has a top opening with a diameter of 80 nm or less.

FIG. 1C illustrates the substrate 100 after a subsequent plasma etch process to etch the underlying layer 110.

The HAR feature in the material layer 120 prepared in FIG. 1B may be used as an etch mask layer for the subsequent plasma etch to form another HAR feature in the underlying layer 110. In various embodiments, the underlying layer 110 may comprise a dielectric material such as silicon oxide and may be etched based on fluorine-based chemistry. In certain embodiments, one or more fluorocarbons may be used as a primary etch gas. For example, a saturated fluorocarbon, an unsaturated fluorocarbon, or a combination thereof may be included in a process gas. In this disclosure, an unsaturated fluorocarbon refers to any compound comprising carbon and fluorine with at least one carbon-carbon double bond (C═C bond) or triple bond (CC bond), and a saturated fluorocarbon refers to any compound comprising carbon and fluorine without any C═C bond or CC bond. In certain embodiments, the unsaturated fluorocarbon may comprise hexafluorobutadiene (C₄F₆), hexafluoro-2-butyne (C₄F₆), or hexafluorocyclobutene (C₄F₆), and the saturated fluorocarbon may comprise octafluoropropane (C₃F₈), perfluorobutane (C₄F₁₀), or perflenapent (C₅F₁₂). In various embodiments, other gases such as a noble gas and/or a balancing agent may also be added. For example, in certain embodiments, argon (Ar) and dioxygen (O₂) may be included as the noble gas and the balancing agent, respectively. In alternate embodiments, the combination of gases may further comprise a third fluorocarbon. In one embodiment, the third fluorocarbon may be octafluorocyclobutane (C₄F₈), octafluoro-2-butene (C₄F₈), hexafluoropropylene (C₃F₆), carbon tetrafluoride (CF₄), or fluoroform (CHF₃).

As illustrated in FIG. 1C, the subsequent plasma etch process may extend the recesses 135 so that it reaches to the top surface of the substrate 100. Accordingly, the subsequent plasma etch process in accordance with various embodiments may provide a good selectivity to silicon (Si) in addition to the mask (e.g., the material layer 120). Consequently, the formation of the recesses 135 may advantageously stop at the top surface of the substrate 100. In certain embodiments, a polymer deposition on the exposed surface of the substrate 100 may advantageously function as an etch stop layer.

In certain embodiments, the subsequent plasma etch process may be advantageously performed as a continuous process with a process time of 60 min or less to form a high aspect ratio (HAR) feature in the underlying layer 110 with an aspect ratio of 50:1 or higher. Further processing may follow conventional processing, for example, by removing any remaining portion of the material layer 120.

In various embodiments, the plasma etch process for the material layer 120 (FIG. 1B) may be performed in a plasma system (e.g., an ICP tool), and the subsequent plasma the etch process for the underlying layer 110 may be performed in another plasma system (e.g., a CCP tool). In alternate embodiments, both two plasma etch processes may be performed in a same plasma system.

FIGS. 2A-2B illustrate cross sectional views of a substrate 100 during the plasma etch process. FIG. 2A illustrates the substrate 100 where etchant species causing lateral etching, and FIG. 2B illustrates the substrate 100 where a passivation layer 220 preventing lateral etching. The structure of the substrate 100 may be identical to those illustrated in FIGS. 1A-1C, and thus will not be repeated.

In FIG. 2A, the substrate 100 is illustrated after performing a plasma etch process in the absence of sidewall passivation of a recess 135. In this example, when etchants 210 (e.g., oxygen species) in the plasma impinge on the sidewalls of the recess 135, they may cause lateral etching, which may then lead to the widening of the recesses 135. Since the degree of lateral etching may vary at different depth of the recess 135, the sidewall of the recess 135 may not be straight. It may be tapered as illustrated in FIG. 2A and/or bowed. Consequently, the HAR feature of the material layer 120 may suffer line wiggling and/or pattern collapse. To avoid such issues, in various embodiments, the sidewall passivation may be enabled and improved by adding a hydrogen-containing gas in the process gas.

In FIG. 2B, the substrate 100 is illustrated after performing a plasma etch process with the sidewall passivation of a recess 135. The sidewall passivation may be achieved by forming the passivation layer 220 comprising H₂O molecules. The passivation layer 220 protects the sidewalls of the recess 135 from the etchants 210.

FIG. 3 illustrates a schematic surface structure of amorphous carbon layer (ACL) with H₂O adsorption.

FIG. 4 illustrates a simulated surface coverage by H₂O as a function of temperature at different partial pressures.

The inventors of this disclosure identified an effective temperature range for H₂O adsorption on ACL (FIG. 3) through quantum chemistry density functional theory (QC-DFT) simulations. The simulated energy of adsorption (E_{ads}) is −0.531 eV, and based on this result, Langmuir surface coverage as a function of temperature is plotted in FIG. 4. Three pressure values (7, 15, and 60 mTorr) are considered. The plots suggest that a temperature of −70° C. may be required for the H₂O physisorption to reach about 20% surface coverage at 60 mTorr, and the temperature may need to be lower for lower pressures. Accordingly, in certain embodiments, during the plasma etch process for ACL, the temperature of the substrate may be kept between −120° C. and −70° C.

FIGS. 5A-5C illustrate process flow diagrams of methods of semiconductor fabrication comprising a plasma etch process to form a HAR feature in accordance with various embodiments. The process flow can be followed with the figures discussed above (e.g., FIGS. 1A-1C) and hence will not be described again.

In FIG. 5A, in accordance with some embodiments, a process flow 50 may start with flowing dioxygen (O₂) and a hydrogen-containing gas (e.g., H₂, hydrocarbon, or H₂O₂) into a plasma processing chamber that holds a substrate comprising an organic layer and a patterned etch mask (block 510, FIG. 1A). Next a plasma may be generated while flowing the gases (block 520). Subsequently, while maintaining the substrate temperature at −50° C. or lower (block 530), the organic layer may be etched to form a recess by exposing the substrate to the plasma (block 540, FIG. 1B).

In FIG. 5B, in accordance with alternate embodiments, a process flow 52 may start with cooling a substrate in a plasma processing chamber to a temperature of −50° C. or lower, where the substrate comprises a dielectric layer, an amorphous carbon layer (ACL) and a patterned etch mask (block 532, FIG. 1A). Next, dioxygen (O₂) and a hydrogen-containing gas may be flowed into the plasma processing chamber (block 510), followed by generating a plasma in the plasma processing chamber, where portions of O₂ and the hydrogen-containing gas react under the plasma to form water (H₂O) molecules (block 522). The substrate may then be exposed to the plasma to form a recess in the organic layer, where the recess has an aspect ratio of at least 20:1 (block 542, FIG. 1B).

In FIG. 5C, in accordance with yet other embodiments, a process flow 54 may start with depositing an amorphous carbon layer (ACL) hardmask over a dielectric layer comprising silicon oxide formed a substrate (block 502), followed by depositing and pattern an etch mask layer over the ACL hardmask (block 504, FIG. 1A). Next, dioxygen(O₂), a hydrogen-containing gas, and a noble gas may be flowed to the plasma processing chamber (block 514). Subsequently, a halogen-free and sulfur-free plasma may be generated in the plasma processing chamber while flowing the gases, where portions of O₂ and the hydrogen-containing gas react under the plasma to form water (H₂O) vapor (block 524). The substrate temperature may then be maintained at −50° C. or lower (block 530). The ACL hardmask may next be patterned by exposing the substrate to the halogen-free and sulfur-free plasma in the plasma processing chamber (block 544, FIG. 1B). After patterning the ACL hardmask, another plasma etch process may be performed to form a HAR feature with an aspect ratio of at least 20:1 in the a dielectric layer by etching the dielectric layer using the patterned ACL hardmask as an etch mask (block 550, FIG. 1C).

FIG. 6 illustrates a plasma system 600 for performing a process of semiconductor fabrication in accordance with various embodiments.

FIG. 6 illustrates the plasma system 600 for performing a plasma etch process, for example, as illustrated in the flow diagrams in FIGS. 5A-5C. The plasma system 600 has a plasma processing chamber 650 configured to sustain plasma directly above a substrate 602 loaded onto a substrate holder 610. A process gas may be introduced to the plasma processing chamber 650 through a gas inlet 622 and may be pumped out of the plasma processing chamber 650 through a gas outlet 624. The gas inlet 622 and the gas outlet 624 may comprise a set of multiple gas inlets and gas outlets, respectively. The gas flow rates and chamber pressure may be controlled by a gas flow control system 620 coupled to the gas inlet 622 and the gas outlet 624. The gas flow control system 620 may comprise various components such as high pressure gas canisters, valves (e.g., throttle valves), pressure sensors, gas flow sensors, vacuum pumps, pipes, and electronically programmable controllers. An RF bias power source 634 and an RF power source 630 may be coupled to respective electrodes of the plasma processing chamber 650. The substrate holder 610 may also be the electrode coupled to the RF bias power source 634. The RF power source 630 is shown coupled to a helical electrode 632 coiled around a dielectric sidewall 616. In FIG. 6, the gas inlet 622 is an opening in a top plate 612 and the gas outlet 624 is an opening in a bottom plate 614. The top plate 612 and bottom plate 614 may be conductive and electrically connected to the system ground (a reference potential).

The plasma system 600 is by example only. In various alternative embodiments, the plasma system 600 may be configured to sustain inductively coupled plasma (ICP) with RF source power coupled to a planar coil over a top dielectric cover, or capacitively coupled plasma (CCP) sustained using a disc-shaped top electrode in the plasma processing chamber 650. Alternately, other suitable configurations such as electron cyclotron resonance (ECR) plasma sources and/or a helical resonator may be used. The RF-bias power source 634 may be used to supply continuous wave (CW) or pulsed RF power to sustain the plasma. Gas inlets and outlets may be coupled to sidewalls of the plasma processing chamber, and pulsed RF power sources and pulsed DC power sources may also be used in some embodiments. In various embodiments, the RF power, chamber pressure, substrate temperature, gas flow rates and other plasma process parameters may be selected in accordance with the respective process recipe.

As described above, various embodiments may use a combination of O₂ and a hydrogen-containing gas (e.g., H₂) for fabricating a high aspect ratio (HAR) feature in, for example, amorphous carbon layer (ACL). The addition of the hydrogen-containing gas may advantageously provide H₂O-based sidewall passivation and also improve the etch rate. The inventors of this application experimentally demonstrated that the addition of H₂ to the process gas increases the amount of dissociated oxygen atom species in the plasma, which may lead to the higher etch rate. The experiments were performed to characterize the plasma composition at −50° C. for six gas flow conditions: 400 sccm O₂; 350 sccm O₂ and 50 sccm H₂; 300 sccm O₂ and 100 sccm H₂; 250 sccm O₂ and 150 sccm H₂; 200 sccm O₂ and 200 sccm H₂; 160 sccm O₂ and 240 sccm H₂. An optical emission spectroscopy (OES) analysis revealed that the emission intensity assigned to oxygen at 700.2 nm was highest with 350 sccm O₂ and 50 sccm H₂ (O₂:H₂ ratio=7:1), followed by 300 sccm O₂ and 100 sccm H₂ (O₂:H₂ ratio=3:1). These two gas flow conditions exhibited higher emission intensity than the baseline condition of 400 sccm O₂ (without H₂) despite the decreased O₂ flow rate. These results suggest the dissociation of O₂ was enhanced by the addition of H₂ with a critical range of oxygen-hydrogen ratio greater than 3:1 in one example. It should be noted, however, that in other embodiments, a different oxygen-hydrogen ratio may be used depending on various process parameters. In further experiments, unexpectedly, about 40% enhancement in etch rate was observed at −50° C. with a gas flow condition of 360 sccm O₂ and 40 sccm H₂ compared to 400 sccm O₂ alone. On the other hand, no substantial improvement in bowing was observed. A better sidewall passivation may be achieved by further lowering the substrate temperature even further to increase the surface coverage with condensed H₂O. The inventors of this application identified that the particular combination of O₂ and a hydrogen-containing gas (e.g., H₂) without halogen-based etch chemistry as well as their particular flow rate ratio and process temperature can be critical in sufficiently providing the effect of H₂O adsorption during etching carbon materials such as ACL.

Example embodiments of the invention are summarized here. Other embodiments can also be understood from the entirety of the specification as well as the claims filed herein.

Example 1. A method of processing a substrate that includes: flowing dioxygen (O₂) and a hydrogen-containing gas into a plasma processing chamber that is configured to hold the substrate, the substrate including an organic layer and a patterned etch mask, the hydrogen-containing gas including dihydrogen (H₂), a hydrocarbon, or hydrogen peroxide (H₂O₂); generating an oxygen-rich plasma while flowing the gases; maintaining a temperature of the substrate in the plasma processing chamber between −150° C. and −50° C.; and while maintaining the temperature, exposing the substrate to the oxygen-rich plasma to form a recess in the organic layer.

Example 2. The method of example 1, where the organic layer includes amorphous carbon layer (ACL).

Example 3. The method of examples 1 or 2, where the temperature of the substrate is between −120° C. and −70° C.

Example 4. The method of one of examples 1 to 3, where a ratio of a flow rate of O₂ to a flow rate of the hydrogen-containing gas is between 100:1 and 1:1.

Example 5. The method of one of examples 1 to 4, further including flowing a noble gas into the plasma processing chamber.

Example 6. The method of one of examples 1 to 5, where the oxygen-rich plasma is a halogen-free plasma.

Example 7. The method of one of examples 1 to 6, where the oxygen-rich plasma is a sulfur-free plasma.

Example 8. The method of one of examples 1 to 7, where the oxygen-rich plasma is an inductively coupled plasma (ICP).

Example 9. The method of one of examples 1 to 8, where portions of O₂ and the hydrogen-containing gas react in the plasma processing chamber to form water (H₂O) vapor that condenses on the substrate while forming the recess.

Example 10. The method of one of examples 1 to 9, where the substrate further includes a dielectric layer below the organic layer, further including, performing an anisotropic etch process to extend the recess into the dielectric layer.

Example 11. A method of processing a substrate that includes: cooling the substrate in a plasma processing chamber to a temperature of −50° C. or lower, the substrate including a dielectric layer, an amorphous carbon layer (ACL) and a patterned etch mask; flowing dioxygen (O₂) and a hydrogen-containing gas into a plasma processing chamber; generating a plasma in the plasma processing chamber, where portions of dioxygen and the hydrogen-containing gas react under the plasma to form water (H₂O) molecules; and exposing the substrate to the plasma to form a recess in the organic layer, the recess having an aspect ratio of at least 20:1, the substrate being kept at around the temperature.

Example 12. The method of example 11, where a ratio of a flow rate of O₂ to a flow rate of the hydrogen-containing gas is between 100:1 and 1:1.

Example 13. The method of one of examples 11 or 12, where the temperature is between −120° C. and −70° C.

Example 14. The method of one of examples 11 to 13, where a total pressure in the plasma processing chamber is kept between 0.1 mTorr and 500 mTorr.

Example 15. The method of one of examples 11 to 14, where the recess defines a feature having a critical dimension between 50 nm and 200 nm.

Example 16. The method of one of examples 11 to 15, where the dielectric layer includes silicon oxide or silicon nitride.

Example 17. A method of forming a high-aspect ratio (HAR) feature on a substrate in a plasma processing chamber that includes: depositing an amorphous carbon layer (ACL) hardmask over a dielectric layer including silicon oxide formed over the substrate; depositing and pattern an etch mask layer over the ACL hardmask; flowing dioxygen(O₂), a hydrogen-containing gas, and a noble gas to a plasma processing chamber; generating a halogen-free and sulfur-free plasma in the plasma processing chamber while flowing O₂, the hydrogen-containing gas, and the noble gas, where portions of O₂ and the hydrogen-containing gas react under the plasma to form water (H₂O) vapor; maintaining a temperature of the substrate between −150° C. and −50° C.; patterning the ACL hardmask by exposing the substrate to the halogen-free and sulfur-free plasma in the plasma processing chamber, while maintaining the temperature of the substrate, to the plasma; and forming a HAR feature in the a dielectric layer by etching the dielectric layer using the patterned ACL hardmask as an etch mask, the HAR feature having an aspect ratio of at least 20:1.

Example 18. The method of example 17, where a ratio of a flow rate of O₂ to a flow rate of the hydrogen-containing gas is between 100:1 and 1:1.

Example 19. The method of one of examples 17 or 18, where a passivation layer is formed on sidewalls of the ACL hardmask while patterning the ACL hardmask, the passivation layer including condensed H₂O.

Example 20. The method of one of examples 17 to 19, where the aspect ratio of the HAR feature is at least 20:1.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method of processing a substrate, the method comprising:
flowing dioxygen (O₂) and a hydrogen-containing gas into a plasma processing chamber that is configured to hold the substrate, the substrate comprising an organic layer and a patterned etch mask, the hydrogen-containing gas comprising dihydrogen (H₂), a hydrocarbon, or hydrogen peroxide (H₂O₂);
generating an oxygen-rich plasma while flowing the gases;
maintaining a temperature of the substrate in the plasma processing chamber between −150° C. and −50° C.; and
while maintaining the temperature, exposing the substrate to the oxygen-rich plasma to form a recess in the organic layer.

2. The method of claim 1, wherein the organic layer comprises amorphous carbon layer (ACL).

3. The method of claim 1, wherein the temperature of the substrate is between −120° C. and −70° C.

4. The method of claim 1, wherein a ratio of a flow rate of O₂ to a flow rate of the hydrogen-containing gas is between 100:1 and 1:1.

5. The method of claim 1, further comprising flowing a noble gas into the plasma processing chamber.

6. The method of claim 1, wherein the oxygen-rich plasma is a halogen-free plasma.

7. The method of claim 1, wherein the oxygen-rich plasma is a sulfur-free plasma.

8. The method of claim 1, wherein the oxygen-rich plasma is an inductively coupled plasma (ICP).

9. The method of claim 1, wherein portions of O₂ and the hydrogen-containing gas react in the plasma processing chamber to form water (H₂O) vapor that condenses on the substrate while forming the recess.

10. The method of claim 1, wherein the substrate further comprises a dielectric layer below the organic layer, further comprising, performing an anisotropic etch process to extend the recess into the dielectric layer.

11. A method of processing a substrate, the method comprising:
cooling the substrate in a plasma processing chamber to a temperature of −50° C. or lower, the substrate comprising a dielectric layer, an amorphous carbon layer (ACL) and a patterned etch mask;
flowing dioxygen (O₂) and a hydrogen-containing gas into a plasma processing chamber;
generating a plasma in the plasma processing chamber, wherein portions of dioxygen and the hydrogen-containing gas react under the plasma to form water (H₂O) molecules; and
exposing the substrate to the plasma to form a recess in the organic layer, the recess having an aspect ratio of at least 20:1, the substrate being kept at around the temperature.

12. The method of claim 11, wherein a ratio of a flow rate of O₂ to a flow rate of the hydrogen-containing gas is between 100:1 and 1:1.

13. The method of claim 11, wherein the temperature is between −120° C. and −70° C.

14. The method of claim 11, wherein a total pressure in the plasma processing chamber is kept between 0.1 mTorr and 500 mTorr.

15. The method of claim 11, wherein the recess defines a feature having a critical dimension between 50 nm and 200 nm.

16. The method of claim 11, wherein the dielectric layer comprises silicon oxide or silicon nitride.

17. A method of forming a high-aspect ratio (HAR) feature on a substrate in a plasma processing chamber, the method comprising:
depositing an amorphous carbon layer (ACL) hardmask over a dielectric layer comprising silicon oxide formed over the substrate;
depositing and pattern an etch mask layer over the ACL hardmask;
flowing dioxygen(O₂), a hydrogen-containing gas, and a noble gas to a plasma processing chamber;
generating a halogen-free and sulfur-free plasma in the plasma processing chamber while flowing O₂, the hydrogen-containing gas, and the noble gas, wherein portions of O₂ and the hydrogen-containing gas react under the plasma to form water (H₂O) vapor;
maintaining a temperature of the substrate between −150° C. and −50° C.;
patterning the ACL hardmask by exposing the substrate to the halogen-free and sulfur-free plasma in the plasma processing chamber, while maintaining the temperature of the substrate, to the plasma; and
forming a HAR feature in the a dielectric layer by etching the dielectric layer using the patterned ACL hardmask as an etch mask, the HAR feature having an aspect ratio of at least 20:1.

18. The method of claim 17, wherein a ratio of a flow rate of O₂ to a flow rate of the hydrogen-containing gas is between 100:1 and 1:1.

19. The method of claim 17, wherein a passivation layer is formed on sidewalls of the ACL hardmask while patterning the ACL hardmask, the passivation layer comprising condensed H₂O.

20. The method of claim 17, wherein the aspect ratio of the HAR feature is at least 20:1.
